(19) United States
(12) Patent Application Publication
(10) Pub. No.: US 2014/0301037 A1
(43) Pub. Date: Oct. 9, 2014

(54) LIQUID COOLANT-SUBMERSIBLE NODE

(71) Applicant: Green Revolution Cooling, Inc., Austin, TX (US)

(72) Inventor: Christiaan Scott Best, Austin, TX (US)

(73) Assignee: Green Revolution Cooling, Inc., Austin, TX (US)

(21) Appl. No.: 14/245,978

(22) Filed: Apr. 4, 2014

Related U.S. Application Data
(60) Provisional application No. 61/853,341, filed on Apr. 4, 2013.

(51) Int. Cl. H05K 7/20

(52) U.S. Cl. CPC H05K 7/20781
USPC 361/679.53; 29/857

(57) ABSTRACT

A node for performing computing operations includes a frame, a power supply coupled to the frame, and one or more liquid coolant-submersible motherboard assemblies. The one or more motherboard assemblies are configured to operate when submersed in a liquid coolant. The motherboard assemblies are mounted on the frame with one or more spaces between. The spaces form one or more channels between the motherboard assemblies. The frame includes an opening on at least one end of the one or more channels.

### PRIORITY CLAIM

This application claims priority to U.S. Provisional Application Ser. No. 61/853,341 entitled “DUAL SERVER NODE” filed Apr. 4, 2013, which is incorporated herein by reference in its entirety.

### BACKGROUND

1. Field

The present invention relates generally to cooling electronic components. More particularly, the present disclosure relates to systems and methods for holding servers in liquid-cooled environments.

2. Description of the Related Art

A data center typically includes a group of computing devices at a common physical location. Data centers are often housed in conventional building structures and use air conditioning systems to remove heat generated by electronic components (chips, hard drives, cards, etc.)

Many commercially-available servers used in data centers are designed for air cooling. Such servers usually comprise one or more printed circuit boards having a plurality of electrically coupled devices mounted thereto. These printed circuit boards are commonly housed in an enclosure having vents that allow external air to flow into the enclosure, as well as out of the enclosure after being routed through the enclosure for cooling purposes. In many instances, one or more fans are located within the enclosure to facilitate this airflow.

Data centers housing such servers and racks of servers typically distribute air among the servers using a centralized fan (or blower). As more fully described below, air within the data center usually passes through a heat exchanger for cooling the air (e.g., an evaporator of a vapor-compression cycle refrigeration cooling system (or “vapor-cycle” refrigeration), or a chilled water coil) before entering a server. In some data centers, the heat exchanger has been mounted to the rack to provide “rack-level” cooling of air before the air enters a server. In other data centers, the air is cooled before entering the data center.

In general, electronic components of higher performing servers dissipate correspondingly more power. However, power dissipation for each of the various hardware components (e.g., chips, hard drives, cards) within a server can be constrained by the power being dissipated by adjacent heating generating components, the airflow speed and airflow path through the server and the packaging of each respective component, as well as a maximum allowable operating temperature of the respective component and a temperature of the cooling air entering the server as from a data center housing the server. The temperature of an air stream entering the server from the data center, in turn, can be influenced by the power dissipation and proximity of adjacent servers, the airflow speed and the airflow path through a region surrounding the server, as well as the temperature of the air entering the data center (or, conversely, the rate at which heat is being extracted from the air within the data center).

It requires a substantial amount of space to house data centers in conventional buildings. In addition, servers deployed in buildings may not portable and may be expensive, as energy costs and power dissipation continue to increase. Air cooling of a data center is also space intensive, because the efficiency of cooling is affected by the proximity of electronic components.

In some data centers, servers are operated in a bath or stream of liquid coolant. The liquid coolant may effectively remove heat from heat-producing components on the servers. Nevertheless, in many rack-based systems, one server cannot be removed or serviced without disrupting operation of other servers in the rack. In addition, some components used in conventional servers are not suited for sustained exposure to liquid coolants. For example, some polymer components, such as polyvinyl chloride connector components, degrade when immersed in some coolant oils.

### SUMMARY

Embodiments of liquid-coolant submersible nodes, and methods of operating and cooling such nodes, are described herein. In an embodiment, a node for performing computing operations includes a frame, a power supply coupled to the frame, and two or more liquid coolant-submersible motherboard assemblies. The motherboard assemblies are configured to operate when submersed in a liquid coolant. The motherboard assemblies are mounted on the frame with one or more spaces between. The spaces form one or more channels between the motherboard assemblies. The frame includes an opening on at least one end of the one or more channels.

In an embodiment, a computing system includes a rack comprising a container that holds liquid coolant. Nodes are mounted in the rack. Each of the nodes includes a frame and one or more motherboard assemblies coupled to the frame. The motherboard assemblies include connector receptacles. The rack holds the nodes in a partially submersed condition such that heat producing components on the one or more motherboard assemblies are submersed in the liquid coolant and at least some of the connector receptacles on the one or more motherboard assemblies of the nodes are above the surface level of the liquid coolant.

In an embodiment, a method of computing includes filling a container of a rack with liquid coolant such that, when one or more nodes is installed in the rack, heat-producing components of the nodes are submersed in the liquid coolant and at least one of the connector receptacles of the nodes is above the surface level of the liquid coolant. The nodes are operated to perform computing operations.

### BRIEF DESCRIPTION OF THE DRAWINGS

FIG. 1A illustrates an embodiment of an exemplary apparatus for cooling one or more independently operable data processing modules in a modular data center.

FIG. 1B illustrates one embodiment of an exemplary system for efficiently cooling a plurality of independently operable data processing modules;

FIG. 1C illustrates an alternative embodiment of an exemplary system for efficiently cooling a plurality of independently operable data processing modules;

FIG. 2 illustrates a cross-sectional front view of a modular data center.

FIG. 3 illustrates a left side view of an exemplary tank

FIG. 4 illustrates a lift system for removing data processing modules from one or more tanks.

FIG. 5 illustrates a cross section view of an embodiment of a lift system for removing data processing modules from one or more tanks.

FIG. 6 illustrates one embodiment of a dual server node with a pair of motherboard assemblies on an open frame.

FIG. 6A illustrates the dual server node with the near wall of the frame removed to show the arrangement of components in a dual server node.

FIG. 7 illustrates one embodiment of a computing system with an array of partially-submersed dual-server nodes.

FIG. 8 illustrates one embodiment of a computing system with an array of partially-submersed dual server nodes with electrical connections above liquid coolant surface level.

FIG. 8A is a detail view illustrating an arrangement of cabling of a dual server node above liquid coolant surface level.

FIGS. 9A and 9B illustrate one embodiment of a dual node server in a partially submersed condition.

FIG. 10 illustrates one embodiment of a node with a motherboard and power supply unit on a common frame.

FIG. 11 illustrates one embodiment of a node with two motherboards and two power supply units.

While the invention is described herein by way of example for several embodiments and illustrative drawings, those skilled in the art will recognize that the invention is not limited to the embodiments or drawings described. It should be understood, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION OF EMBODIMENTS

In various embodiments, one or more liquid cooled data processing modules are integrated into a shipping container.

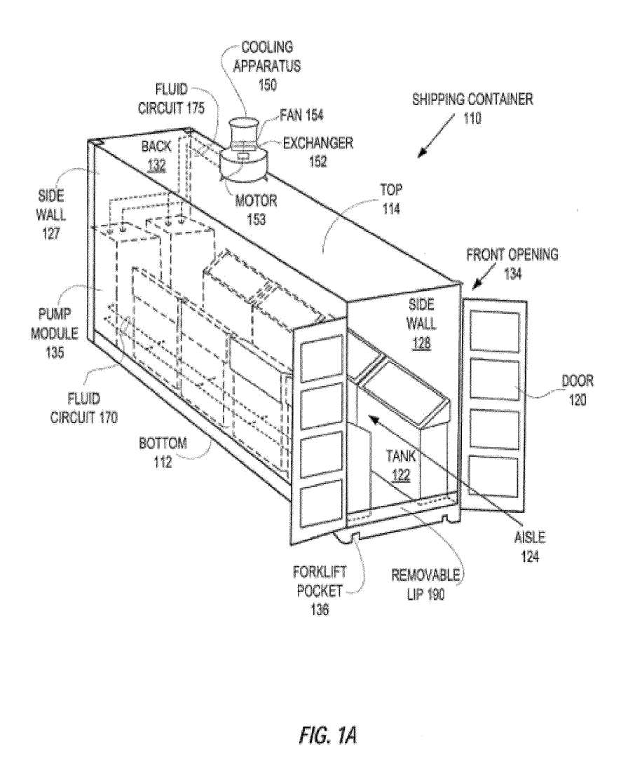

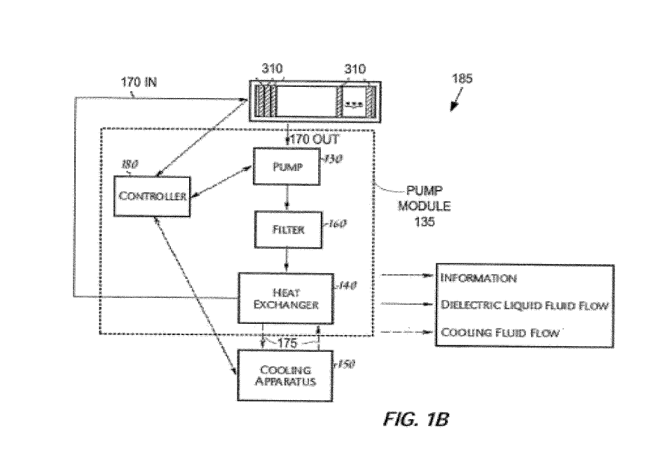

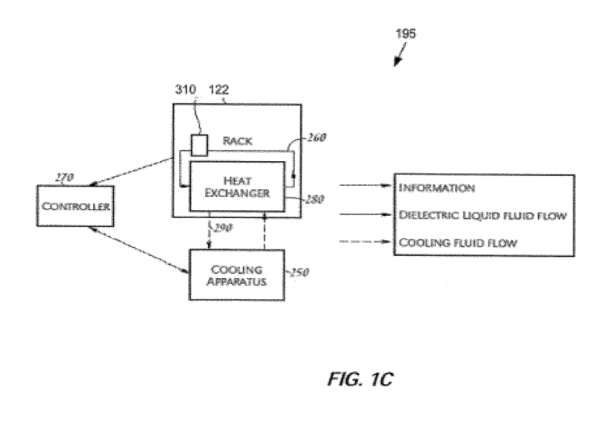

FIG. 1A depicts an exemplary, liquid cooled modular data center, for operating one or more independently operable data processing modules containing heat-generating electronic components arranged in one or more tanks The modular data center includes a shipping container 110 having a bottom 112 and a top 114. Standard ISO shipping containers are 10, 20, or 40 ft. in length. Shipping container 110 has a back wall 132, opposing side walls 127 and 128, and a front opening 134, wherein front opening 134 is normally provided with a door 120.

Inside shipping container 110, a plurality of tanks 122 are provided, each tank 122 containing vertically mounted, independently removable and replaceable data processing modules. As shown in FIG. 1A, tanks 122 are arranged in two banks adjacent an aisle 124. The tanks may be arranged otherwise. For example, a single bank of tanks 122 may be installed in the center of shipping container 110 with aisles on either side of tanks 122. Or a single bank of tanks 122 may be installed against a wall of shipping container 110, for example.

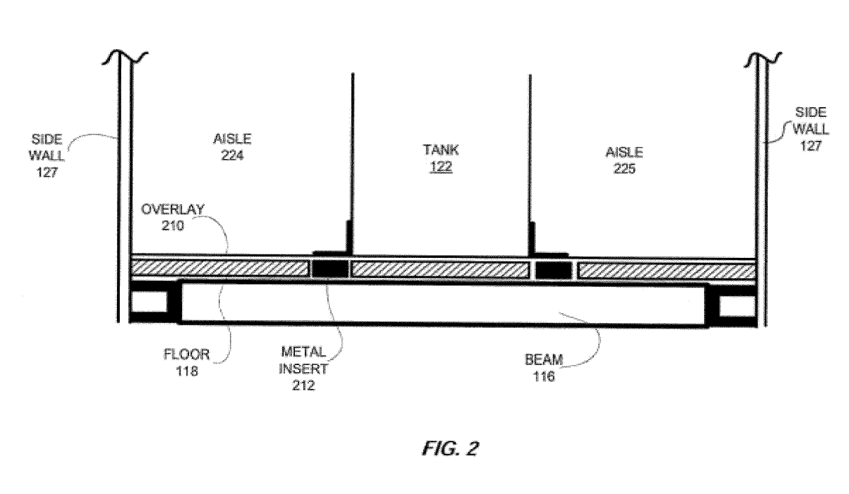

Referring now to FIG. 2, a front plan cross section view of the modular data center is presented, according to an embodiment of the present invention. As depicted in FIG. 2, tanks 122 are arranged in a single bank in the center of shipping container 110 with aisles 224 and 225 on either side of tanks 122, although this is just one of other possible arrangements, as previously stated. Overlay 210, which may be sheet metal, is provided on top of floor 118 of shipping container 110 and is sealed at least to side walls 127 and 128 and back wall 132 to create a liquid tight barrier to hold liquid coolant in the event of a leak from tank 122 or from lines of the cooling system carrying the liquid coolant as hereinafter described. Other materials may be provided for overlay 210, such as plastic or other suitable material, and overlay 210 may also be sealed to front 134 of shipping container 110.

According to one or more embodiments of the present invention, a front lip 190 is provided at the threshold of front opening 134, which requires a user to step over lip 190 when entering shipping container 110. Lip 190 is preferably sealed in removable fashion to walls 127 and 128 and overlay 210, such that the seal provided by lip 190 is sufficient to keep any spilled liquid coolant from coming out of container 110 via front opening 134. The top edge of lip 190 is a sufficient height above overlay 210 such that the volume defined by the exposed surface area of overlay 210 and height of top edge of lip 190 is at least 110% of the volume of liquid coolant in one tank 122.

Lip 190 is of a suitable material for sealing. In one or more embodiments, lip 190 is substantially rigid metal or plastic, for example, wherein lip 190 seals in a removable fashion so that removal enables rolling tanks 122, pumping modules 135 and other equipment in and out of container 110. Lip 190 may alternatively include a soft material such as a deformable foam or plastic that deforms when a heavy object rolls over it but pops back into place afterwards, such as a Build-a-Berm barrier, which is commercially available by Pig. (“Build-a-Berm” and “Pig” are trademarks of New Pendulum Corp.) The seal by lip 190 where lip 190 interfaces walls 127 and 128 and overlay 210 may be maintained at least partly by pressure of lip 190 against walls 127 and 128 and overlay 210 and maybe facilitated also by a gasket against the surface of lip 190 that faces walls 127 and 128 and overlay 210. The seal may be also or alternatively enhanced by a sealing compound, such as a nitrile rubber, for example.

In one or more embodiments, edges of overlay 210 (i.e., edges at walls 127, 128 and 132 and at front 135) may be turned up and joined, such as by welding, adhesive, gaskets, etc., wherein the turned up and joined edges of overlay 210 provide sides for the container, so that overlay 210, including its sides, provides a liquid tight container. More generally, sides may be provided at edges of overlay 210 (i.e., edges at walls 127, 128 and 132 and at front 135) in any suitable manner, which may include berm-type sides, so that overlay 210, including its sides, provides a liquid tight container. In this case, the edges or sides of overlay 210 are not necessarily sealed to container 110, although they may be.

Shipping container 110 comprises at least one beam 116 integrated into the bottom 112 and a floor 118 installed on top of the at least one beam 116. Floor 118 is typically a wooden floor, such as 28 mm plywood, for example, to which fasteners may be secured and that is disposed above bottom 112 and supported by the at least one beam 116. Alternatively, floor 118 may include other materials such as plastic or metal.

One or more data processing modules in one or more tanks 122 containing liquid coolant are installed on top of overlay 210. Tanks 122 are secured so they are fixed in position within container 110, which may be by attaching fasteners (e.g., bolted) through overlay 210 and floor 118, into beam 116, which is integrated into bottom 112 of shipping container 110. Penetrations through overlay 210 are sealed, such that liquid cannot leak through. In some cases, a metal insert 212 may be put in place between the beam and tanks 122. Tanks 122 may also be secured by other means to overlay 210, such as by welding or adhesive, for example.

In the embodiment depicted in FIG. 2, beam 116 runs essentially from one sidewall 127 to the other sidewall 128 and has an “I” shaped cross-section profile, which is obtained by two rails on each end facing sidewalls 127 and 128, where the end rails are connected to a rail in the middle, as shown. Floor 118 is supported by a plurality of such beams 116 in the depiction of FIG. 2, although only one such beam 116 is visible in the figure. Beam 116 may have other configurations, including non-I shaped profiles. Rather than providing beams 116 running from one sidewall to the other, one or more beams 116 may be provided running lengthwise, that is, from front 134 to back 132.

Referring now to FIG. 1A in connection with FIG. 2, according to one or more embodiments of the present invention, a front lip 190 is provided at the threshold of front opening 134, which requires a user to step over lip 190 when entering shipping container 110. Lip 190 is preferably sealed in removable fashion to walls 127 and 128 and overlay 210, such that the seal provided by lip 190 is sufficient to keep any spilled liquid coolant from coming out of container 110 via front opening 134. The top edge of lip 190 is a sufficient height above overlay 210 such that the volume defined by the exposed surface area of overlay 210 and height of top edge of lip 190 is at least 110% of the volume of liquid coolant in one tank 122.

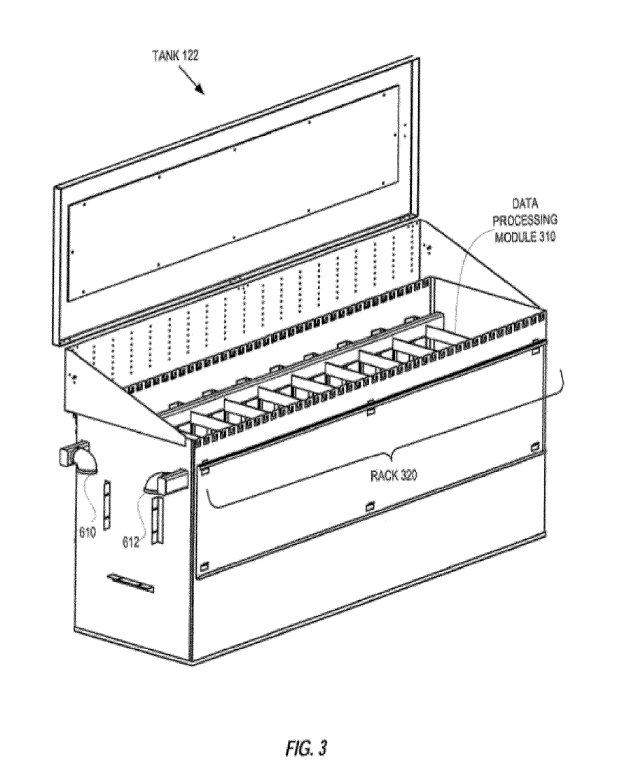

Referring now to FIG. 3, a side view of tank 122 is depicted. Tank 122 may optionally have a hinged or removable lid (shown open in FIG. 3) or an open top. Tank 122 may be fabricated of steel, a sufficiently strong plastic that is compatible with the liquid coolant used as a cooling medium, or other suitable material. Tank 122 may face upward with an open top to form an open interior volume. Tank 122 may contain a plurality of independently operable data processing modules 310 mounted vertically and independently removable and replaceable from tank 122. Each data processing module 310 is independently removable and replaceable without affecting the position or operation of other data processing modules. The independently operable data processing modules 310 may be mounted in an array arranged horizontally and immersed at least partially in liquid coolant.

Referring now to FIG. 1B, shipping container 110 may include a cooling system 185 for transferring heat from data processing modules 310. The liquid coolant heated by data processing modules 310 is fluidly coupled through suitable piping or lines to a pump 130, which pumps the heated liquid coolant through suitable piping or lines to a heat exchanger 140 associated with a heat-rejection or cooling apparatus 150. In some embodiments, heat exchanger 140 is remotely or distally located from tank 122 and/or shipping container 110. Heat exchanger 140 rejects the heat from the incoming heated liquid coolant and fluidly couples the cooled liquid coolant through a return fluid line or piping 170 back into the tank 122. Thus, at least a portion of the liquid coolant completes a fluid circuit through the data processing modules 310 in tank 122, pump 130, heat exchanger 140, and back into tank 122. The heat rejected from the heated liquid coolant through the heat exchanger 140 may then be selectively used by alternative heat rejection or cooling apparatus 150 to dissipate, recover, or beneficially use the rejected heat depending on the different environmental conditions or data processing modules 310 operating conditions to which the system is subject.

Referring now to FIG. 1C, an embodiment of an alternative cooling system 195 is illustrated for cooling data processing modules 310. Unlike the cooling system 185, heated liquid coolant does not flow outside the tank 122. Instead, one fluid circuit 260 of the flowing liquid coolant is completely internal to the tank 122. A thermal coupling device 280, such as a heat exchanger, is mounted within the tank 122 within the fluid circuit through the data processing modules 310, so that at least a portion of the heated liquid coolant flow exiting the data processing modules flows through the thermal coupling device 280. Cooled liquid coolant exits the coupling device 280 and at least a portion of the cooled dielectric coolant circulates in the internal fluid circuit 260 back through the data processing modules 3 10.

Cooling systems 185 (FIG. 1B) and 195 (FIG. 1C) include a computer controller 180 with suitable novel applications software for implementing the methods of the present invention. A detailed description of controller 180 is included in co-pending international published patent application WO 2010019517 which is incorporated by reference, as stated herein above.

Referring now to FIGS. 1A and 1B, cooling apparatus 150, which provides an evaporative final heat exchanger 152 and a motor 153 driven fan 154 for forcing air flow through final heat exchanger 152, is located sufficiently far away from tanks 122 to enable adequate heat dissipation at exchanger 152 to cool the heated liquid in loop 175. The resulting heat may be vented to the ambient outside environment. Alternately, the resulting heat may be beneficially used, as described in co-pending PCT patent application WO 2013022805. The cooled liquid is then recirculated through the return pipe in loop 175 to cool the liquid coolant in loop 170 which, in tum, cools the data processing modules 310 in tanks 122. (Heat exchanger 152, fan 154 and motor 153 are shown schematically, are not to scale and may be arranged differently than shown.) In one or more embodiments of the present invention, cooling apparatus 150 is mounted on the exterior top of container 110. This is advantageous because it allows deploying the data center contained by shipping container 110 as a single “block,” which is faster. With cooling tower 150 physically attached to container 110, structural support is provided by container 110, eliminating the need to pour concrete supports for cooling towers.

Although one cooling apparatus 150 is shown, more than one may be provided in various embodiments of the present invention. For example, one cooling apparatus 150 may be provided for each bank of tanks 122. Further, cooling loops 175 may be arranged, and each cooling apparatus 150 may be sized, so that a plurality of cooling apparatus 150 may provide backup cooling for one other. Cooling apparatus 150 need not be attached to the shipping container.

As shown in FIG. 1A, a module 135, which may include at least elements as shown in FIG. 1B, for example, is provided for tanks 122, according to one or more embodiments of the present invention. That is, according to one or more embodiments, each pump module 135 may include primary and secondary pumps 130 (and associated pump motors) connected to filter 160 and liquid coolant heat exchanger 140 of at least one bank of tanks 122 via fluid circuit 170 such that primary and secondary pumps 130 may function independently of one another for backup purposes, with electrically isolated pump 130 motors. According to one or more embodiments, primary pump 130 motor is controlled by variable speed controller 180 for regulating temperature of coolant loop 170 by varying liquid coolant flow, whereas secondary pump 130 motor is fixed-speed and controlled by on-off control.

Also provided is a module 135 for evaporative cooling apparatus 150 according to one or more embodiments of the present invention, which includes a controller for controlling a pump motor in loop 175, which may be on-off control or variable speed control, according to one or more embodiments, and includes a controller for fan 154 motor 153, which may be like controller 180 of FIG. 1B, for example, but for regulating fan 154 speed of evaporative cooling apparatus 150 in order to control temperature of loop 175 by varying air flow over evaporative final heat exchanger 152. A pump, motor controller and cooling water loop may also be provided to run water over the exterior of heat exchanger 152 for additional cooling.

According to one or more embodiments of the present invention, where cooling tower 150 is integrated with container 110, as shown in FIG. 1A, for example, liquid coolant of loop 170 may be run directly to heat exchanger 152 of cooling tower 150 in a closed loop, rather than providing separate loop 175. A pump and cooling water loop may be provided to run water over the exterior of heat exchanger 152 during hot periods in addition to the air drawn through exchanger 152 by fan 154, while during cold periods the water is not needed because air through exchanger 152 provides sufficient cooling. This dramatically reduces the amount of water used for cooling.

Controllers 180 may be interfaced via a network with a master controller for which a single dashboard is provided, according to one or more embodiments of the present invention, which is for displaying and controlling water flow in one or more loops 175 through one or more cooling towers 150, fan power for air flow across the one or more heat exchangers of 152 one or more cooling towers 150, and liquid coolant flow in one or more loops 170 for tanks 122. Preferably, the master controller optimizes all elements for minimum power consumption of the system while maintaining sufficient cooling. The network controller performs diagnostic testing of each element separately for functionality and reports the functionality back to a single user. This single management point makes the system more reliable and more efficient, since the master controller can obtain maximum efficiency for all components.

Insulation is provided for exterior walls 127, 128 and 132 of container 110, as well as for doors 120, according to one or more embodiments of the present invention. The insulation may include a spray on coating added to the inside or outside of container 110 and may include dirt piled on top 114, possibly with grass growing on the surface, since dirt and grass provide excellent insulation. This reduces the amount of solar heating to container 110 during the summer, making it easier for people to work therein and service the data processing modules 310 and other equipment. The lower ambient temperature also makes the power distribution equipment more reliable. Additional safety equipment may include a non-slip floor, an emergency exit, motion detection and other security.

Referring now to FIG. 5 in conjunction with FIG. 1A, a lift system 500 is provided in container 100 for removing data processing modules 310 from one or more tanks 122, in one or more embodiments of the present invention. In this embodiment, transport rails 520A and B are mounted fixedly to side walls 127 and 128, with traveling bridge 524 spanning transport rails 520A and B on rollers (not shown), so that traveling bridge 524 is configured for moving the length of transport rails 520A and B, which may be the length of container 110 from front 134 to back 132 or may be the width from side wall 127 to side wall 128, depending on orientation of lift system 500 within container 110. (It should be understood that transport rails 520A and B may alternately be mounted in other ways within container 110, such as directly to top 114, for example.)Trolley 528 is configured to roll along the length of traveling bridge 524, i.e., from one transport rail 520A to the other 520B, with hoist 530 suspended from trolley 528. Hoist 530 has a cable and hook configured to be attached to data processing module 310 so that hoist 530 can raise and lower data processing module 310 from tank 122, which is filled with liquid coolant. When hoist 530 has raised a data processing module 310 out of tank 122, trolley 528 can roll along traveling bridge 524 and traveling bridge 524 can roll along transport rails 520A and B to move the data processing modules 310 to a different location. Thus, a user may position hoist 530 over a data processing module and pick the data processing module out of the liquid coolant to perform data processing module maintenance, for example.

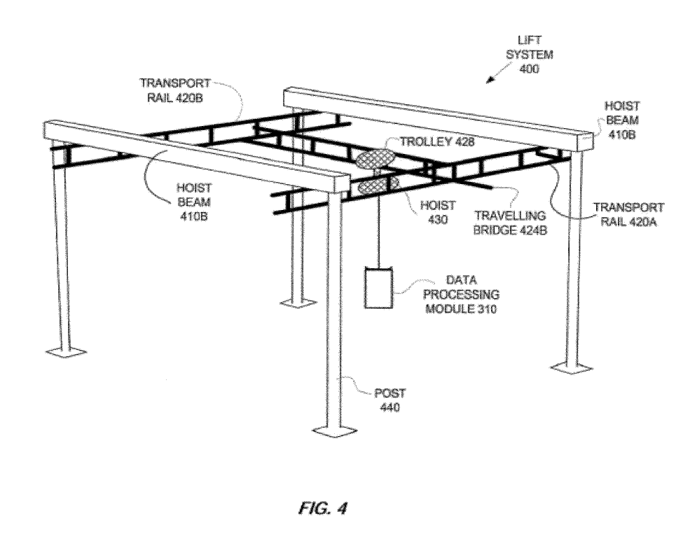

Referring now to FIG. 4 in conjunction with FIG. 1A, a lift system 400 provided in container 110 for removing data processing modules 310 from one or more tanks 122 is depicted, according to one or more embodiments of the present invention, wherein hoist beams 410 are rigidly fixed to and supported by posts 440, which may stand upon overlay 210 (FIG. 2) and may be fixed thereto or to floor 118 (FIG. 2) or beam 116 (FIG. 2). Transport rails 420A and B are mounted fixedly to hoist beams 410A and B, with a traveling bridge 424 spanning transport rails 420A and B on rollers (not shown), so that traveling bridge 424 is configured for moving the length of transport rails 420A and B, which may be the length of container 110 from front 134 to back 132 or may be the width from side wall 127 to side wall 128, depending on the orientation of lift system 400 within container 110. (It should be understood that transport rails 420A and B may alternately be mounted directly on posts 440 without hoist beams 41 OA and B.)Trolley 428 is configured to roll along the length of traveling bridge 424, i.e., from one transport rail 420A to the other 420B, with hoist 430 suspended from trolley 428. Hoist 430 has a cable and hook configured to be attached to data processing module 310 so that hoist 430 can raise and lower data processing module 310 from tank 122, which is filled with liquid coolant. When hoist 430 has raised a data processing module 310 out of tank 122, trolley 428 can roll along traveling bridge 424 and traveling bridge 424 can roll along transport rails 420A and B to move the data processing modules 310 to a different location. Thus, a user may position hoist 430 over a data processing module and pick the data processing module out of the liquid coolant to perform data processing module maintenance, for example.

In one or more alternative embodiments, a gantry crane configuration is provided for lift system 400, wherein posts 440 are not fixed to the container, but rather include rollers, with transport rails 420A and B extending less than the entire length or width of container 110. Thus, according to one such gantry crane configuration, posts 440 roll from front 134 to back 132 or from side wall 127 to side wall 128, depending on orientation of lift system 400 within container 110.

As used herein, the terms comprises, comprising, or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as essential or critical.

In some embodiments, a system includes modules that can be removed without interrupting other compute modules. The nodes may be placed in a rack holding a set of nodes mounted vertically and submersed.

In some embodiments, two motherboards share a power supply unit (PSU). PSUs may be at least double the thickness of the motherboards, so pairing the boards may approximately match the width required for the PSU. The motherboards may be connected to the PSU with a “Y” connector or a connector that disconnects so the mother board can be pulled from the node and pressed back in. The motherboards may be size to protrude the connectors above the cooling fluid so the connecting cables are not submerged.

In some embodiments, the servers are turned off when removed from the cooling system and the rack. The servers may turn on by grounding a wire to the chassis Grounding may be accomplished by either a manual switch or a pressure switch that is activated when the node is inserted into the rack.

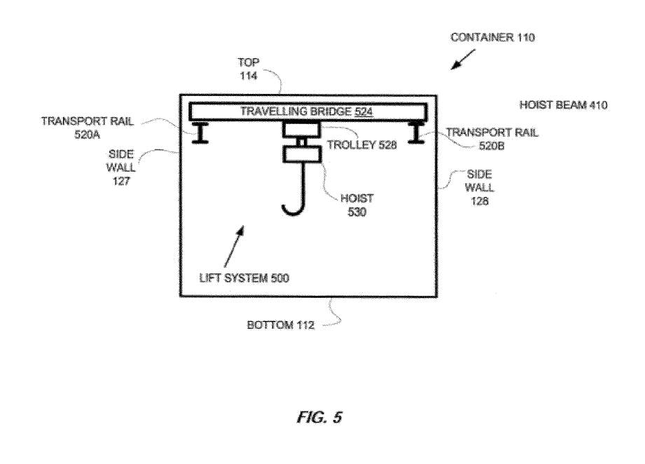

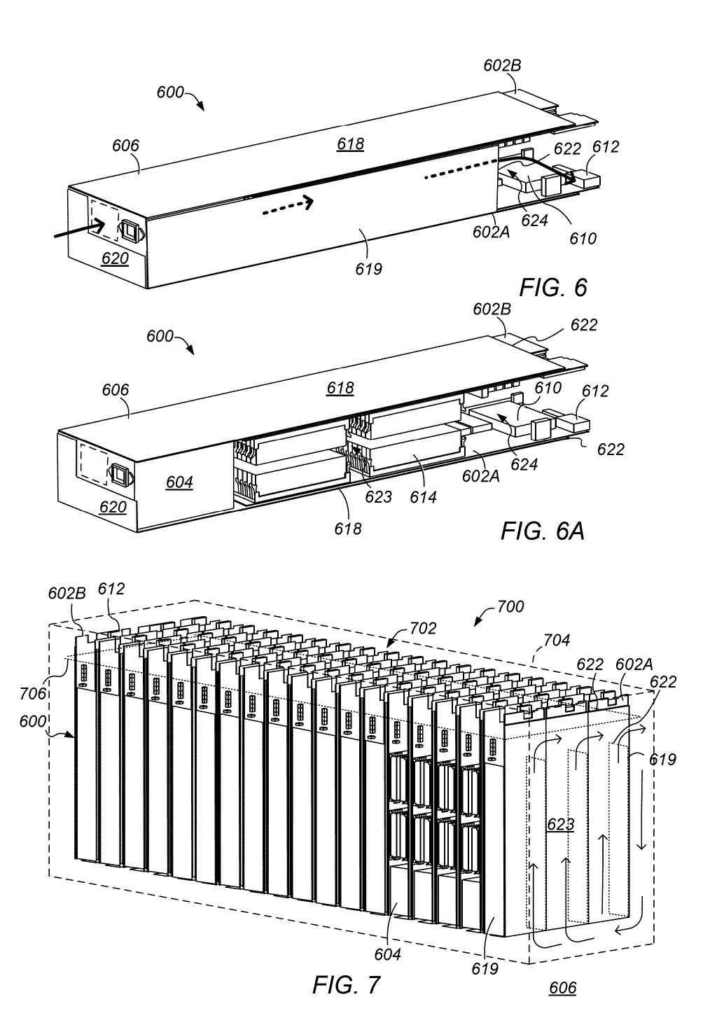

FIG. 6 illustrates one embodiment of a dual server node with a pair of motherboard assemblies on an open frame. FIG. 6A illustrates the dual server node with the near wall of the frame removed to show the arrangement of the components in the dual server node. Node 600 includes motherboard assemblies 602A and 602B, power supply unit 604, and frame 606. Motherboard assemblies 602A and 602B and power supply unit 604 are commonly mounted on frame 606. Each of motherboard assemblies 602A and 602B may operate as a server independent from the other motherboard assembly.

Each of motherboard assemblies 602A and 602B includes central processing unit 610, board-mount connector receptacle 612, and memory modules 614. Central processing unit 610, memory modules 614, and other components on motherboard assemblies 602A and 602B may produce heat during operation of node 600. In some embodiments, expansion cards may be installed on motherboard 602A and 602B (for example, in PCI-E slots.

Motherboard assemblies 602A and 602B of node 600 may be connected to power supply unit 604. Power supply unit 604 may receive power from a power distribution unit. The power distribution unit may be inside or outside of the rack in which node 600 is installed. Power supply unit 604 may supply power to electrical components of motherboard assemblies 602A and 602B. Motherboard assemblies 602A and 602B may be connected to power supply unit 604 by way of a Y-cable.

Frame 606 includes panels 618, panels 619, and bottom panel 620. In one embodiment, frame 606 is made of sheet metal that has been formed into a u-shape. Side panels 618 may form the legs of the “U” and bottom panel 620 may form the base of the “U”.

Motherboard assemblies 602A and 602B may each have a width that is about half the width of power supply unit 604 (width, as used here, is the dimension of the motherboard assembly spanning between opposing panels 618 of frame 606). In some embodiments, motherboard assemblies 602A and 602B each have a width that is less than half the width of power supply unit 604.

Each of motherboard assemblies 602A and 602B include a portion that extends beyond panels 618 of frame 606, panels 619 of frame 606, or both. Specifically, part of motherboard assemblies 602A and 602B extends beyond edges 622. Connector receptacles 612 are located on the part of part of motherboard assemblies 602A and 602B that extends beyond edge 622 of panels 619 on frame 606.

Power supply unit 604 may allow liquid to pass through its housing by way of inlet 625. In some embodiments, passages in node 600 allow fluid to pass through opening 625 of power supply unit 604, across components on motherboard assemblies 602A and 602B, and out of the node by way of one or more openings on the sides of frame 606, such as opening 624 (such as shown by the arrows in FIG. 6).

Channel 623 is formed between opposing motherboard assemblies 602A and 602B. Opening 624 to channel 624 is formed between the edges of opposing side panels 618. In some embodiments, frame 606 includes openings on both ends of the channel (for example, at near and far edges of panel 618 shown in FIG. 6. Openings on both ends of the channel may allow for continuous flow of liquid coolant through channel 624.

FIG. 7 illustrates one embodiment of a computing system with an array of partially-submersed dual-server nodes. Computing system 700 includes an array 702 of nodes 600 in rack 704. In FIG. 7, rack 704 is shown in dashed lines as a simple box for clarity. Rack 704 may include a container that holds liquid coolant (for example, a tank). Rack 704 may also include a frame, enclosure, rails, and other structural elements for housing and supporting nodes in array 702. In FIG. 7, panels 619 on some of nodes 600 are removed for illustrative purposes. Each of nodes 600 may be separately removable from rack 704. In some embodiments, each of nodes 600 may be vertically removed from rack 704 without disturbing operation of the other nodes in rack 704.

Nodes 600 are installed such that motherboard assemblies 602A and 602B are vertically arranged in rack 702. Each pair of motherboard assemblies 602A and 602B resides in a space directly above a power supply unit 604, which may supply power to the motherboard assemblies and/or other components in the rack.

A portion of each motherboard assembly may extend above the surface level 706 of liquid coolant in rack 702. Connector receptacles 612 may remain above surface level 706, whether nodes 600 are operating or not operating (for example, during service or replacement of nodes 600.

In some embodiments, a pump is used to circulate liquid coolant through nodes in a rack. In the embodiment shown in FIG. 7, liquid coolant may be pumped (for example, from front to back, or bottom to top) through channels in nodes 600. In certain embodiments, a controller, such as described herein relative to FIGS. 1A or 1B may be used to control cooling using liquid coolant in a rack container.

FIG. 7 illustrates one example of liquid coolant flow through nodes mounted in a rack. The arrows near the right side of FIG. 7 illustrate circulation. A pump may circulate liquid coolant through all of the nodes. In each row, liquid coolant may flow through channels 623 of the nodes, out of the node over edge 622 of panels 619, and down back to the bottom of the tank.

In some embodiments, mounting members of a rack (for example, rack 704) are configured to mount the servers closely adjacent to one another in the server rack to restrict the flow of the dielectric liquid coolant between the vertically-oriented servers, such that the flow of the dielectric liquid coolant through the servers is enhanced

In some embodiments, a temperature of the oil monitored and/or controlled. Methods of monitoring and controlling temperature of the oil may be as described in U.S. Patent Publication No. 2011/0132579 (the “'579 Publication”), by Best et al., published Jun. 9, 2011, which is incorporated by reference in its entirety as if fully set forth herein.

In some embodiments, flow through the servers in augmented using augmentation, such as nozzles, fans, or pumps. A separate augmentation device may be included on each each node, every other node, each row of nodes, or other frequency. The '579 Publication describes apparatus and methods using augmentation devices in various embodiments.

In some embodiments, liquid coolant may be removed through the top of the rack. Liquid coolant may be reintroduced after having been cooled (for example, by passing the liquid coolant through a heat exchanger outside of the rack. The '579 Publication describes apparatus and methods for removing liquid coolant from the top of a rack in various embodiments.

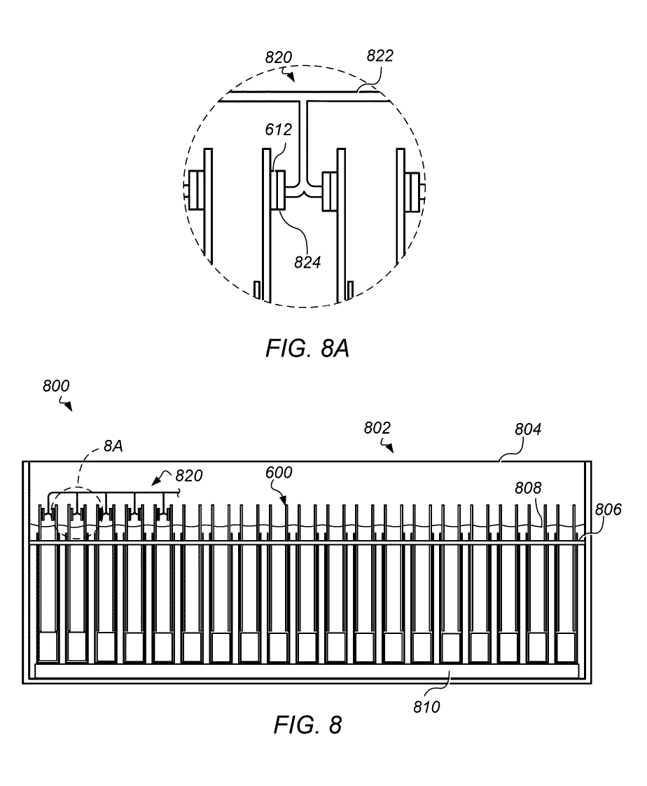

FIG. 8 illustrates one embodiment of a computing system with an array of partially-submersed dual server nodes with electrical connections above liquid coolant surface level. Computing system 800 includes nodes 600 in rack 802. Rack 802 includes container 804 and rails 806 (only the front rail of a pair of opposing rails is shown in FIG. 8 for clarity). Node 600 includes dual motherboard assemblies 602A and 602B. Each of nodes 600 is mounted on rails 806. Each node can be separately removed in the rack.

Container 804 holds liquid coolant. Liquid coolant 808 is filled to liquid coolant surface level 808. A portion of motherboard assemblies 602A and 602B extends above liquid coolant surface level. Structural elements for holding nodes in a rack may be built in to a submersion cooling rack or may be separate components.

In some embodiments, power distribution for nodes is integrated into a frame, so that when a node is dropped in, a power connector connects to a power supply unit. In FIG. 8, for example, power supply unit 604 may couple with power distribution unit 810. Power distribution unit 810 includes blind mate connector receptacles. The blind mate connector receptacles may couple with a corresponding plug on power supply unit 604. In some embodiments, power is automatically enabled to a node when the node is installed in the rack.

FIG. 8A is a detail view illustrating an arrangement of cabling of a dual-server node above liquid coolant surface level. Cable assembly 820 includes cable 822 and connector plugs 824. Each of connector plugs 824 may couple with one of connector receptacles 612 on one of motherboard assemblies 602A and 602B. Cable assembly 820, including cable 822 and connector plugs 824, and all of connector receptacles 612, may remain above the surface level of liquid coolant in the container.

In embodiments described above, a node is installed such that the motherboards are in a vertical orientation. Motherboards may nevertheless in some embodiments be in a horizontal orientation.

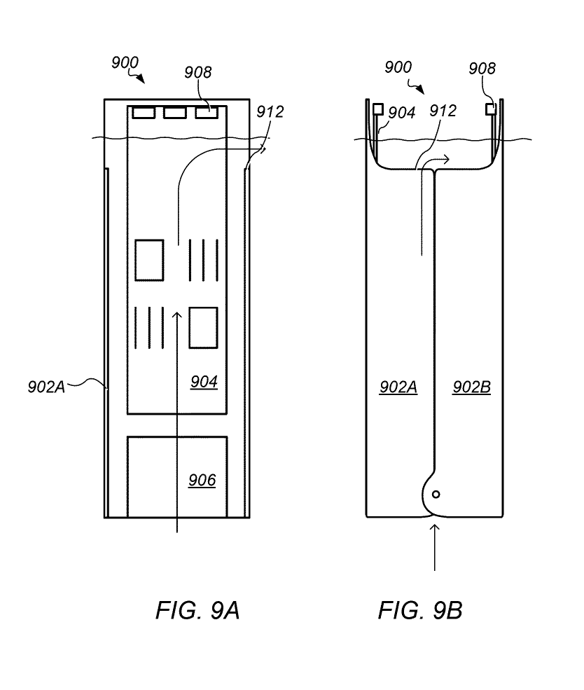

FIGS. 9A and 9B illustrate one embodiment of a dual node server in a partially submersed condition. Node 900 has hinged frame with opposing frame halves 902A and 902B. A motherboard assembly 904 is mounted on each of the frame halves. A power supply unit 906 may be mounted to either of the frame halves. Connector receptacles 908 may be above a liquid coolant level when node 900 is installed in a rack. Edges 912 of frame halves 902A and 902B may be below the connector receptacles. Edges 912 may also be below liquid coolant level when node 900 is installed in a rack. Flow in node 900 may be from top to bottom as shown by the arrows.

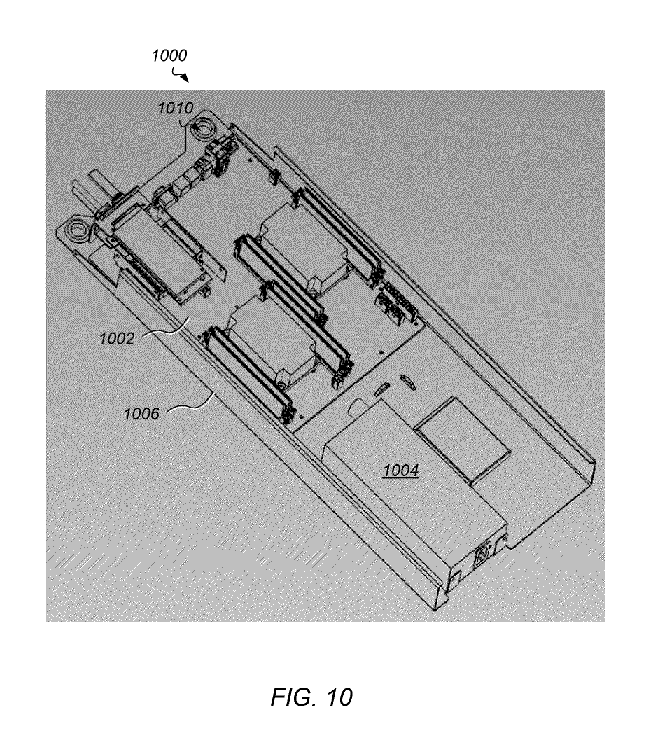

In some embodiments, a node includes a motherboard and power supply unit on a common frame. FIG. 10 illustrates one embodiment of a node with a motherboard and power supply unit. Node 1000 includes motherboard assembly 1002 and power supply unit 1004 of sled 1006. Node 1000 includes finger holes 1010, which may be used to vertically remove node 1000 from a rack. In some embodiments, node 1000 is coupled to another node (for example, with motherboards in a face-to-face arrangement).

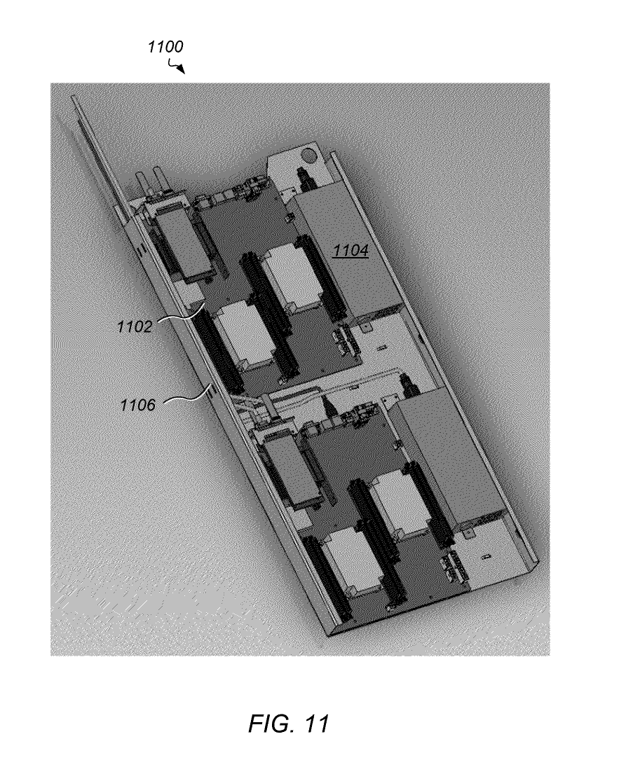

In some embodiments, a node includes multiple motherboard assemblies, with corresponding power supply units, on a common frame. FIG. 11 illustrates one embodiment of a node with two motherboards and two power supply units. Node 1100 includes motherboard assemblies 1102 and power supply units 1104 of sled 1106. In some embodiments, node 1100 is coupled to another node (for example, with each of the motherboard in a face-to-face arrangement with a motherboard on the other node).

Although the systems illustrated in FIGS. 5 through 8A depict nodes having two motherboards, nodes may in various s embodiments have any number of motherboards or other components. In one embodiment, for example, a node has 3 motherboards in parallel spaced relationship to one other.

In various embodiments described herein, a system has been described as holding motherboard assemblies in a submersed or partially submersed condition. A system may nevertheless in various embodiments hold other types of circuit board assemblies or components in a partially submersed condition.

As used herein, the terms “or” is intended to cover a non-exclusive inclusion. That is, “or” includes both meanings of both “or” and “and/or.”

The terminology used herein is for the purpose of describing particular embodiments only and is not intended to be limiting of the invention. As used herein, the singular forms “a”, “an” and “the” are intended to include the plural forms as well, unless the context clearly indicates otherwise.

As used herein, the term “data processing module” generally refers to one or more computing devices running software configured to receive requests, typically over a network. A data processing module may include one or more servers connected to a network and running software configured to receive requests from other computing devices on the network, which may include other servers, and desktop and mobile computing devices, including cellular phones. Such data processing modules typically include one or more processors, memory, input/output connections to a network and other electronic components, and may include specialized computing devices such as blade servers, network routers, data acquisition equipment, disc drive arrays, and other devices commonly associated with data centers.

As used herein, the term “shipping container” refers to a commercially available shipping container that is used to transport goods on ships, trains and trucks, and which may be of a standardized size and configuration.

As used herein, the term “node” refers to a computing device that can be configured to receive and respond to requests to perform computing operations. A node may have one processor or multiple processors. In some embodiments, a node includes one or more servers and/or one or more data processing modules.

As used herein, the term “tank” refers to a container with or without a lid, containing a liquid coolant into which one or more data processing modules may be installed.

As used herein, an “independently operable” device means capable of usefully functioning without regard to an operational status of an adjacent device. As used herein, an “independently operable data processing module” means a data processing module that is capable of usefully functioning to provide data processing services and without regard to an operational status of an adjacent data processing module. Operation of independently operable data processing modules can be influenced (e.g., heated) by one or more adjacent data processing modules, but as used herein, an independently operable data processing module generally functions regardless of whether an adjacent data processing module operates or is operable.

As used herein, the term “liquid coolant” may be any sufficiently nonconductive liquid such that electrical components (e.g., a motherboard, a memory board, and other electrical or electronic components designed for use in air) continue to reliably function while submerged without significant modification. A suitable liquid coolant is a dielectric liquid coolant, including without limitation vegetable oil, mineral oil, transformer oil, or any liquid coolant have similar features (e.g., a non-flammable, non-toxic liquid with dielectric strength better than or nearly as comparable as air).

As used herein, “fluid” means either a liquid or a gas, and “cooling fluid” means a gas or liquid coolant typically used for heat-rejection or cooling purposes. As used herein, a liquid coolant is a subset of the universe of cooling fluids, but a cooling fluid may be a dielectric or non-dielectric liquid or gas, such as, for example, a conventional air conditioning refrigerant.

The flowchart and block diagrams in the drawings illustrate the architecture, functionality, and operation of possible implementations of systems, methods and program products, according to various embodiments of the present invention.

While this specification contains many specifics, these should not be construed as limitations on the scope of the invention or of what can be claimed, but rather as descriptions of features specific to particular implementations of the invention. Certain features that are described in this specification in the context of separate implementations can also be implemented in combination in a single implementation. Conversely, various features that are described in the context of a single implementation can also be implemented in multiple implementations separately or in any suitable sub combination. Moreover, although features can be described above as acting in certain combinations and even initially claimed as such, one or more features from a claimed combination can in some cases be excised from the combination, and the claimed combination can be directed to a sub combination or variation of a sub combination.

Similarly, the separation of various system components in the implementations described above should not be understood as requiring such separation in all implementations, and it should be understood that the described program components and systems can generally be integrated together in a single software product or packaged into multiple software products.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, parts and processes may be reversed, and certain features of the invention may be utilized independently, all as would be apparent to one skilled in the art after having the benefit of this description of the invention. Methods may be implemented manually, in software, in hardware, or a combination thereof. The order of any method may be changed, and various elements may be added, reordered, combined, omitted, modified, etc. Changes may be made in the elements described herein without departing from the spirit and scope of the invention as described in the following claims.

1. A node for performing computing operations, comprising:
a frame;
one or more power supply units coupled to the frame; and
one or more liquid coolant-submersible motherboard assemblies coupled to the frame, wherein the motherboard assemblies are configured to operate when submersed in a liquid coolant,
wherein the frame includes an opening on at least one end of at least one of the channels, wherein the opening is configured to allow liquid coolant to flow in or out of the frame.

2. The node of claim 1, wherein the frame comprises openings on either end of the channel, wherein the openings allow liquid-coolant to flow through the channel when the node is submersed in liquid coolant.

3. The node of claim 1, wherein the frame comprises one or more bottom openings on or proximate to the bottom of the node and one or more side openings on one or more sides of the nodes, wherein the bottom openings allow liquid-coolant to flow into the channel from the bottom and out through one or more side openings when the node is submersed in liquid coolant.

4. The node of claim 1, wherein the motherboard assemblies comprise connector receptacles, wherein the motherboard assemblies are coupled to the frame such that the connector receptacles are at or proximate to the top of the node when the node is vertically mounted in a rack.

5. The node of claim 1, wherein the motherboard assemblies comprise connector receptacles, wherein the motherboard assemblies are coupled to the frame such that the connector receptacles are configured to protrude above a surface level of liquid coolant when the node is partially submersed in liquid coolant.

6. The node of claim 1, wherein the frame is U-shaped, wherein at least one of the one or more openings is formed between the edges of the frame.

7. The node of claim 1, wherein the frame comprises sheet metal with one or more openings to at least one of one or more channels.

8. The node of claim 1, wherein the one or more motherboard assemblies comprise two or more motherboard assemblies, wherein the two or more motherboard assemblies are mounted on the frame with one or more spaces between, wherein the one or more spaces form one or more channels between the at least two motherboard assemblies,

9. The node of claim 1, wherein the one or more motherboard assemblies comprise two or more motherboard assemblies, wherein the one or more power supply units comprises two power supply units, wherein each of the power supply units supplies power to one of the motherboard assemblies.

10. The node of claim 1, wherein at least two of the motherboard assemblies face one another across the channel.

11. The node of claim 1, wherein the node is configured to automatically power up when the node is installed in the rack.

12. A computing system, comprising:
a rack comprising a container configured to hold liquid coolant;
liquid coolant in the container; and
one or more nodes mounted in the rack,
wherein at least one of the nodes comprises a frame and one or more motherboard assemblies coupled to the frame, wherein the one or more motherboard assemblies comprise one or more connector receptacles,
wherein rack is configured to hold the nodes in a partially submersed condition when liquid coolant is held in the container such that heat producing components on the one or more motherboard assemblies are submersed in the liquid coolant and one or more connector receptacles on the one or more motherboard assemblies of at least one of the nodes is above the surface level of the liquid coolant.

13. The computing system of claim 12, wherein at least one of the nodes is installed such that at least two of the motherboard assemblies are vertically oriented in the rack.

14. The computing system of claim 12, wherein the one or more nodes comprises a row of nodes, wherein each of at least two of the nodes is partially submersed such that a connector receptacle of the motherboard assembly is above the surface level of the liquid coolant.

15. The computing system of claim 12, further comprising one or more cables interconnecting motherboard assemblies of at least two of the nodes, wherein the rack is configured to hold the connector receptacles and at least one of the cables above the surface level of the liquid coolant.

16. The computing system of claim 12, wherein at least one of the frames for at least one of the nodes is integrated with the rack.

17. The computing system of claim 12, wherein the frame comprises openings on either end of the channel, wherein the openings allow liquid-coolant to flow through the channel when the node is submersed in liquid coolant.

18. The computing system of claim 12, wherein the motherboard assemblies comprise connector receptacles, wherein the motherboard assemblies are coupled to the frame such that the connector receptacles are at or proximate to the top of the node when the server is vertically mounted in a rack.

19-22. (canceled)

23. A method of computing, comprising:
filling a container of a rack with liquid coolant such that, when one or more nodes is installed in the rack, at least one heat producing components of the node is submersed in the liquid coolant and at least one connector receptacle of the server node is above the surface level of the liquid coolant; and
operating at least one node in the rack to perform computing operations.

24. The method of claim 23, wherein operating at least one node in the rack to perform computing operations comprises connecting one or more cables such that the cables are above the surface-level of the liquid coolant in the rack.

25. (canceled)
